(19) United States
(12) Patent Application Publication
(10) Pub. No.: US 2025/0253251 A1
(43) Pub. Date: Aug. 7, 2025

(54) SEMICONDUCTOR INTEGRATED CIRCUIT DEVICE

(71) Applicant: Socionext Inc., Kanagawa (JP)

(72) Inventor: Toshio HINO, Yokohama-shi (JP)

(21) Appl. No.: 19/184,527

(22) Filed: Apr. 21, 2025

Related U.S. Application Data
(63) Continuation of application No. PCT/JP2023/039287, filed on Oct. 31, 2023.

(30) Foreign Application Priority Data
Nov. 9, 2022 (JP) 2022-179665

(51) Int. Cl. H01L 23/538; H10D 84/83

(52) U.S. Cl. CPC H01L 23/5384; H01L 23/5386; H10D 84/832

(57) ABSTRACT

A capacitor cell includes an active region and a power line supplying VDD. The active region includes nanosheets extending in the X direction as channels of transistors. The power line extends in the X direction on the back side of the transistors and overlaps the active region in planar view. The sources/drains of the transistors in the active region are connected to the power line through vias. VSS is supplied to gate interconnects of the transistors.

### CROSS-REFERENCE TO RELATED APPLICATIONS

This is a continuation of International Application No. PCT/JP2023/039287 filed on Oct. 31, 2023, which claims priority to Japanese Patent Application No. 2022-179665 filed on Nov. 9, 2022. The entire disclosures of these applications are incorporated by reference herein.

### BACKGROUND

The present disclosure relates to a semiconductor integrated circuit device.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, whereby an LSI chip is designed.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised a problem. To solve this problem, three-dimensional transistors, of which the transistor structure has changed from the conventional planar structure to a three-dimensional structure, have been vigorously studied. A nanosheet FET is one example of such three-dimensional transistors.

The recent progress toward further miniaturization and higher integration in semiconductor integrated circuits is significant. With this, reduction in operating voltage and speedup in operating frequency are being accelerated. However, with the speedup, noise increases, and with the voltage reduction, noise immunity decreases, causing a problem that noise-caused circuit malfunctions tend to occur in recent semiconductor integrated circuits. As a method for preventing noise-caused circuit malfunctions, there is a method in which a decoupling capacitor is provided between power supplies of a circuit. A cell having such a decoupling capacitor is called a capacitor cell.

WO 2021/171969 discloses a capacitor cell using nanosheet FETs.

US Patent Application Publication No. 2021/375853 discloses, for further higher integration, a technique of providing interconnects on the back of a substrate right under transistors and connecting the sources/drains of the transistors to the interconnects.

As of today, however, no examination has been made on the layout structure of capacitor cells in which interconnects are provided right under transistors.

An objective of the present disclosure is presenting a layout structure of a capacitor cell in which interconnects are provided right under transistors.

### SUMMARY

According to the first mode of the disclosure, a semiconductor integrated circuit device including a standard cell that is a capacitor cell is provided. The standard cell includes: a first active region forming a channel, source, and drain of a first transistor of a first conductivity type and including a first nanosheet extending in a first direction as the channel of the first transistor; a first power line formed on the back side of the first transistor, extending in the first direction, having an overlap with the first active region in planar view, and supplying a first power supply voltage; vias formed at positions where the source and drain of the first transistor in the first active region overlap the first power line, to connect the source and drain to the first power line; and a first gate interconnect extending in a second direction perpendicular to the first direction, being orthogonal to the first nanosheet in planar view, and being supplied with a second power supply voltage.

According to the above mode, the first active region forms the channel, source, and drain of the first transistor. The first power line supplying the first power supply voltage is formed on the back side of the first transistor and has an overlap with the first active region in planar view. The source and drain of the first transistor are connected to the first power line overlapping in planar view through vias. The first gate interconnect that is to be the gate of the first transistor is supplied with the second power supply voltage, whereby the first transistor functions as a capacitor. Also, since the first power line overlaps the first active region in planar view and the source and drain of the first transistor are connected to the first power line through vias, the area of the layout structure is reduced. Thus, reduction in the area of the capacitor cell can be achieved.

According to the present disclosure, it is possible to achieve reduction in the area of a capacitor cell in which interconnects are provided right under transistors.

### BRIEF DESCRIPTION OF THE DRAWINGS

FIG. 1 is a plan view showing an example of the layout structure of a capacitor cell according to the first embodiment.

FIGS. 2A and 2B are cross-sectional views of the capacitor cell of FIG. 1 taken horizontally in planar view.

FIGS. 3A and 3B are cross-sectional views of the capacitor cell of FIG. 1 taken vertically in planar view.

FIG. 4 is a circuit diagram of the capacitor cell shown in FIGS. 1, 2A, 2B, 3A, and 3B.

FIGS. 5A and 5B show another configuration example of the semiconductor integrated circuit device according to the embodiment.

FIG. 6 is a plan view showing an example of the layout structure of a capacitor cell according to Alteration 1 of the first embodiment.

FIG. 7 is a circuit diagram of the capacitor cell shown in FIG. 6.

FIG. 8 is a plan view showing an example of the layout structure of a capacitor cell according to Alteration 2 of the first embodiment.

FIG. 9 is a circuit diagram of the capacitor cell shown in FIG. 8.

FIG. 10 is a plan view showing a layout structure of a capacitor cell according to the second embodiment.

FIG. 11 is a circuit diagram of the capacitor cell shown in FIG. 10.

### DETAILED DESCRIPTION

Embodiments of the present disclosure will be described hereinafter with reference to the accompanying drawings. In the following embodiments, it is assumed that the semiconductor integrated circuit device includes a plurality of standard cells (hereinafter simply called cells as appropriate), and at least some of the standard cells include nanosheet field effect transistors (FETs). The nanosheet FET is a FET using a thin sheet (nanosheet) through which a current flows. Such a nanosheet is formed of silicon, for example. Note however that, in the present disclosure, the transistors included in the standard cells are not limited to nanosheet FETs.

As used herein, “VDD” and “VSS” refer to the power supply voltages or the power supplies themselves. Also, as used herein, an expression indicating that sizes such as widths are identical, like the “same wiring width,” is to be understood as including a range of manufacturing variations.

### First Embodiment

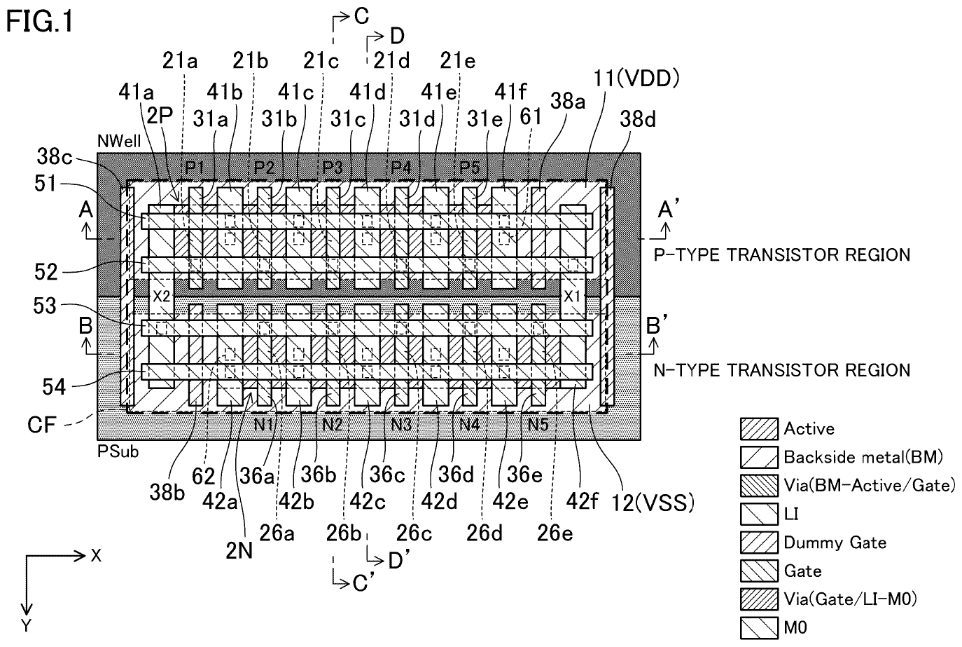

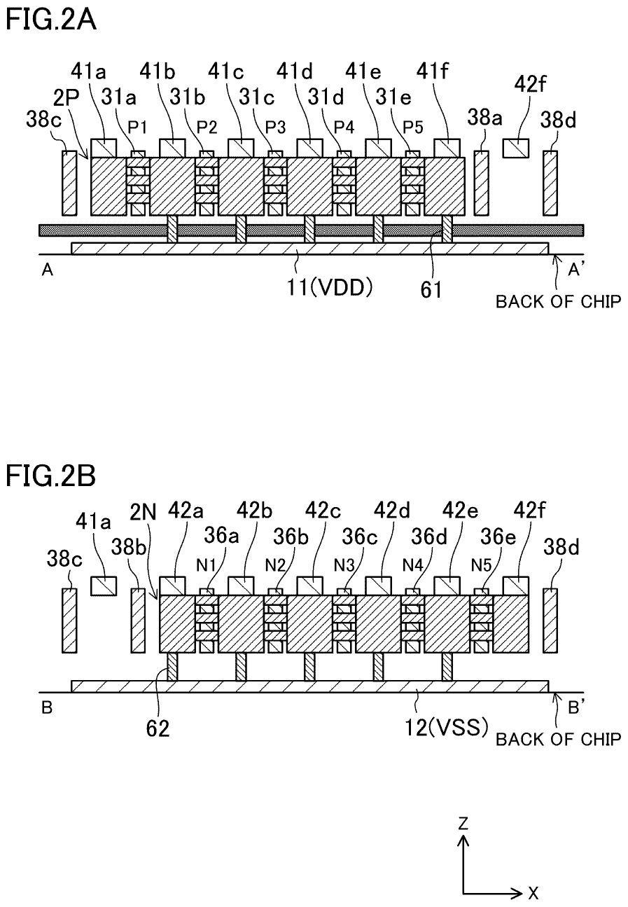

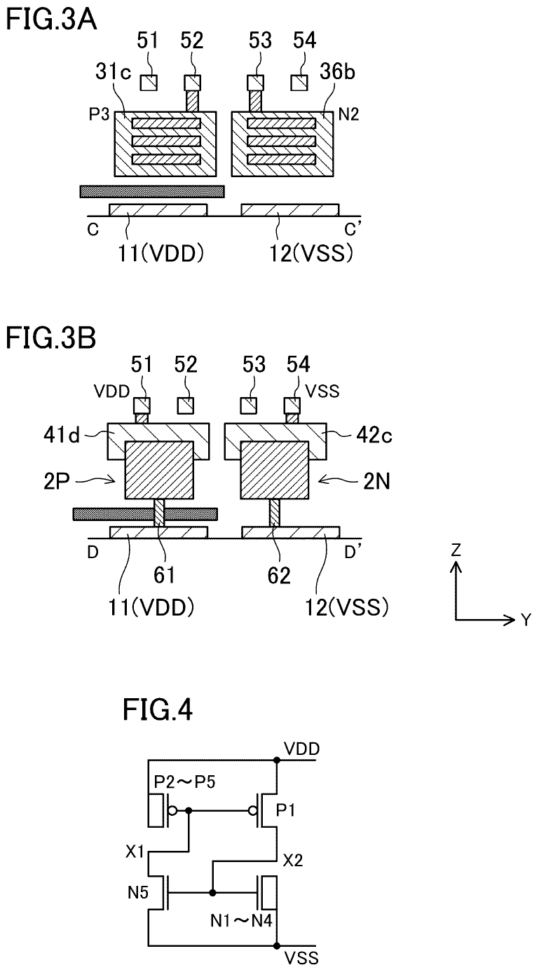

FIGS. 1, 2A-2B, and 3A-3B are views showing an example of the layout structure of a capacitor cell included in a semiconductor integrated circuit device according to the first embodiment, where FIG. 1 is a plan view, FIGS. 2A and 2B are cross-sectional views taken horizontally in planar view, and FIGS. 3A and 3B are cross-sectional views taken vertically in planar view. Specifically, FIG. 2A shows a cross section taken along line A-A′, FIG. 2B shows a cross section taken along line B-B′, FIG. 3A shows a cross section taken along line C-C′, and FIG. 3B shows a cross section taken along line D-D′.

Note that, in the plan views such as FIG. 1, the horizontal direction in the figure is hereinafter referred to as an X direction (corresponding to the first direction), the vertical direction in the figure as a Y direction (corresponding to the second direction), and the direction perpendicular to the substrate plane as a Z direction.

FIG. 4 is a circuit diagram of the capacitor cell shown in FIGS. 1, 2A-2B, and 3A-3B. As shown in FIG. 4, the capacitor cell has p-type transistors P1, P2, P3, P4, and P5 and n-type transistors N1, N2, N3, N4, and N5. The transistors P1 to P5 and the transistors N1 to N5 function as capacitors. The transistor P1 and the transistor N5 constitute a fixed value output unit. The fixed value output unit outputs a low fixed value (VSS) to a node X1 and a high fixed value (VDD) to a node X2. The transistor P1 is connected to VDD at its source, to the gate of the transistor N5 at its drain, and to the drain of the transistor N5 at its gate. The transistor N5 is connected to VSS at its source and to the gate of the transistor P1 at its drain. The gate of the transistor P1 corresponds to the node X1, and the gate of the transistor N5 corresponds to the node X2.

The transistors P2 to P5 are connected to VDD at their sources and drains and to the node X1 at their gates. Since VSS is output to the node X1 from the fixed value output unit, the transistors P2 to P5 function as capacitors. The transistors N1 to N4 are connected to VSS at their sources and drains and to the node X2 at their gates. Since VDD is output to the node X2 from the fixed value output unit, the transistors N1 to N4 function as capacitors. Since the transistor P1 is connected to VDD at its source, to the node X2 (=VDD) at its drain, and to the node X1 (=VSS) at its gate, it functions as a capacitor. Since the transistor N5 is connected to VSS at its source, to the node X1 (=VSS) at its drain, and to the node X2 (=VDD) at its gate, it functions as a capacitor.

The capacitor cell of FIGS. 1, 2A-2B, and 3A-3B and other standard cells are arranged in a row in the X direction with the cell frame CF of each cell being in contact with adjacent ones, thereby constituting a cell row. A plurality of such cell rows are arranged in the Y direction with the cell frame CF being in contact with adjacent ones. Note that such cell rows are flipped vertically every other row.

Power lines 11 and 12 extending in the X direction are formed in an interconnect layer provided on the back of the semiconductor chip in which the transistors are formed. The power line 11 supplies the power supply voltage VDD, and the power line 12 supplies the power supply voltage VSS. The power lines 11 and 12 are shared with other cells in the cell row including the capacitor cell, to serve as power lines extending in the X direction. Also, each of the power lines 11 and 12 is shared with a cell row adjacent in the Y direction.

In a p-type transistor region on an n-type well (NWell), an active region 2P forming the channels, sources, and drains of the p-type transistors is formed. The active region 2P overlaps the power line 11 in planar view.

In the p-type transistor region, the p-type transistors P1, P2, P3, P4, and P5 are formed in this order from the left in FIG. 1. The transistors P1, P2, P3, P4, and P5 have nanosheets 21a, 21b, 21c, 21d, and 21e, respectively, each of a structure of three sheets lying one above another and extending in the X direction. That is, the transistors P1, P2, P3, P4, and P5 are nanosheet FETs. In the active region 2P, portions that are to be the sources and drains of the transistors P1, P2, P3, P4, and P5 are connected to the power supply 11 through vias 61 except for the left portion of the transistor P1 in the figure.

In an n-type transistor region on a p-type substrate (PSub), an active region 2N forming the channels, sources, and drains of the n-type transistors is formed. The active region 2N overlaps the power line 12 in planar view. Note that the n-type transistor region may be formed on a p-type well.

In the n-type transistor region, the n-type transistors N1, N2, N3, N4, and N5 are formed in this order from the left in FIG. 1. The transistors N1, N2, N3, N4, and N5 have nanosheets 26a, 26b, 26c, 26d, and 26e, respectively, each of a structure of three sheets lying one above another and extending in the X direction. That is, the transistors N1, N2, N3, N4, and N5 are nanosheet FETs. In the active region 2N, portions that are to be the sources and drains of the transistors N1, N2, N3, N4, and N5 are connected to the power supply 12 through vias 62 except for the right portion of the transistor N5 in the figure.

Note that, in the active regions, the portions that are to be the sources and the drains on both sides of the nanosheets are formed by epitaxial growth from the nanosheets.

The p-type transistor region and the n-type transistor region are formed adjacent to each other in the Y direction. The positions of the transistors P2, P3, P4, and P5 are respectively the same as the positions of the transistors N1, N2, N3, and N4 in the X direction. That is, the transistors P2 and N1 are arranged in line in the Y direction, the transistors P3 and N2 are arranged in line in the Y direction, the transistors P4 and N3 are arranged in line in the Y direction, and the transistors P5 and N4 are arranged in line in the Y direction.

In the p-type transistor region, gate interconnects 31a, 31b, 31c, 31d, and 31e extending in parallel in the Y direction are formed. Also, a dummy gate interconnect 38a that does not constitute a transistor is formed on the right side of the gate interconnect 31e in the figure. The gate interconnects 31a, 31b, 31c, 31d, and 31e and the dummy gate interconnect 38a have the same width and are placed at the same pitch.

In the n-type transistor region, gate interconnects 36a, 36b, 36c, 36d, and 36e extending in parallel in the Y direction are formed. Also, a dummy gate interconnect 38b that does not constitute a transistor is formed on the left side of the gate interconnect 36a in the figure. The dummy gate interconnect 38b and the gate interconnects 36a, 36b, 36c, 36d, and 36e have the same width and are placed at the same pitch.

The positions of the gate interconnects 31a, 31b, 31c, 31d, and 31e and the dummy gate interconnect 38a are respectively the same as the positions of the dummy gate interconnect 38b and the gate interconnects 36a, 36b, 36c, 36d, and 36e. That is, the gate interconnect 31a and the dummy gate interconnect 38b are arranged in line in the Y direction, the gate interconnects 31b and 36a are arranged in line in the Y direction, the gate interconnects 31c and 36b are arranged in line in the Y direction, the gate interconnects 31d and 36c are arranged in line in the Y direction, the gate interconnects 31e and 36d are arranged in line in the Y direction, and the dummy gate interconnect 38a and the gate interconnect 36e are arranged in line in the Y direction.

Also, dummy gate interconnects 38c and 38d are formed on the side portions of the cell frame CF in the X direction. The dummy gate interconnect 38c is shared with a cell placed on the left in the figure, and the dummy gate interconnect 38d is shared with a cell placed on the right in the figure.

The gate interconnect 31a surrounds the peripheries of the nanosheets 21a of the transistor P1 in the Y and Z directions via gate insulating films (not shown). The gate interconnect 31a is to be the gate of the transistor P1. Similarly, the gate interconnects 31b, 31c, 31d, and 31e surround the peripheries of the nanosheets 21b, 21c, 21d, and 21e of the transistors P2, P3, P4, and P5, respectively, in the Y and Z directions via gate insulating films (not shown). The gate interconnects 31b, 31c, 31d, and 31e are to be the gates of the transistors P2, P3, P4, and P5, respectively.

The gate interconnect 36a surrounds the peripheries of the nanosheets 26a of the transistor N1 in the Y and Z directions via gate insulating films (not shown). The gate interconnect 36a is to be the gate of the transistor N1. Similarly, the gate interconnects 36b, 36c, 36d, and 36e surround the peripheries of the nanosheets 26b, 26c, 26d, and 26e of the transistors N2, N3, N4, and N5, respectively, in the Y and Z directions via gate insulating films (not shown). The gate interconnects 36b, 36c, 36d, and 36e are to be the gates of the transistors N2, N3, N4, and N5, respectively.

Local interconnects 41a, 41b, 41c, 41d, 41e, 41f, 42a, 42b, 42c, 42d, 42e, and 42f extending in the Y direction are formed in a local interconnect layer. The local interconnects 41a, 41b, 41c, 41d, 41e, and 41f are connected to the portions that are to be the sources and drains of the transistors P1, P2, P3, P4, and P5 in the active region 2P. The local interconnects 42a, 42b, 42c, 42d, 42e, and 42f are connected to the portions that are to be the sources and drains of the transistors N1, N2, N3, N4, and N5 in the active region 2N. The local interconnect 41a extends from the p-type transistor region over to the n-type transistor region. The local interconnect 42f extends from the n-type transistor region over to the p-type transistor region.

Metal interconnects 51, 52, 53, and 54 extending in the X direction are formed in an M0 interconnect layer that is a metal interconnect layer located above the local interconnect layer. The metal interconnect 51 is connected to the local interconnects 41b, 41c, 41d, 41e, and 41f through vias. The metal interconnect 52 is connected to the gate interconnects 31a, 31b, 31c, 31d, and 31e through vias. The metal interconnect 52 is also connected to the local interconnect 42f through a via. The metal interconnect 53 is connected to the gate interconnects 36a, 36b, 36c, 36d, and 36e through vias. The metal interconnect 53 is also connected to the local interconnect 41a through a via. The metal interconnect 54 is connected to the local interconnects 42a, 42b, 42c, 42d, and 42e through vias.

The metal interconnect 52 and the local interconnect 42f correspond to the node X1 of the circuit and are supplied with VSS as the fixed value. The metal interconnect 53 and the local interconnect 41a correspond to the node X2 of the circuit and are supplied with VDD as the fixed value. The metal interconnect 51 is connected to the power line 11 through the local interconnects 41b, 41c, 41d, 41e, and 41f and the active region 2P, and supplied with VDD. The metal interconnect 54 is connected to the power line 12 through the local interconnects 42a, 42b, 42c, 42d, and 42e and the active region 2N, and supplied with VSS.

In the capacitor cell of this embodiment, the active region 2P overlaps the power line 11 formed in the interconnect layer on the back of the chip in planar view. The vias 61 are placed at positions overlapping the source/drain regions in the active region 2P in planar view, to connect the active region 2P and the power line 11. Also, the active region 2N overlaps the power line 12 formed in the interconnect layer on the back of the chip in planar view. The vias 62 are placed at positions overlapping the source/drain regions in the active region 2N in planar view, to connect the active region 2N and the power line 12. With this configuration, reduction in the area of the capacitor cell is achieved.

Also, the metal interconnect 51 is supplied with VDD, and the metal interconnect 52, corresponding to the node X1, is supplied with the fixed value VSS. The metal interconnect 53, corresponding to the node X2, is supplied with the fixed value VDD, and the metal interconnect 54 is supplied with VSS. Therefore, the metal interconnects 51, 52, 53, and 54 form interconnect capacitances.

Here, description will be made focusing on the transistor P3 functioning as a capacitor. In the transistor P3, VSS is supplied from the node X1 to the gate interconnect 31c that is to be its gate, and VDD is supplied to its source and drain through the local interconnects 41c and 41d. This produces capacitances with gate oxide films of the transistor P3 interposed in between. Also, capacitances are produced in the following portions:
1) between the source/drain and the gate interconnect 31c (see FIG. 2A);
2) between the local interconnects 41c and 41d and the gate interconnect 31c (see FIG. 2A);
3) between the gate interconnect 31c and the gate interconnect 36b of the transistor N2 (see FIG. 3A);
4) between the source/drain and the source/drain of the transistor N2 (see FIG. 3B);
5) between the local interconnects 41c and 41d and the local interconnects 42b and 42c (see FIG. 3B);
6) between the gate interconnect 31c and the power line 11 (see FIG. 2A); and
7) between the power line 11 and the power line 12 (see FIGS. 3A and 3B).

In particular, 6) and 7) above are capacitances produced by forming the power lines 11 and 12 under the transistors. As for 7), a greater capacitance can be achieved because the power line 11 and the power line 12 are located close to each other.

As described above, according to this embodiment, in the transistor P3, for example, the channel, the source, and the drain are formed in the active region 2P. The power line 11 supplying VDD, formed on the back side of the transistor P3, overlaps the active region 2P in planar view. The source and drain of the transistor P3 are connected to the power line 11, overlapping in planar view, through the vias 61. The gate interconnect 31c that is to be the gate of the transistor P3 is connected to the metal interconnect 52 to which the fixed value VSS is supplied. Therefore, the transistor P3 functions as a capacitor. Also, since the power line 11 overlaps the active region 2P in planar view and the source and drain of the transistor P3 are connected to the power line 11 through the vias 61, the area of the layout structure is reduced.

Also, in the transistor N2, for example, the channel, the source, and the drain are formed in the active region 2N. The power line 12 supplying VSS, formed on the back side of the transistor N2, overlaps the active region 2N in planar view. The source and drain of the transistor N2 are connected to the power line 12, overlapping in planar view, through the vias 62. The gate interconnect 36b that is to be the gate of the transistor N2 is connected to the metal interconnect 53 to which the fixed value VDD is supplied. Therefore, the transistor N2 functions as a capacitor. Also, since the power line 12 overlaps the active region 2N in planar view and the source and drain of the transistor N2 are connected to the power line 12 through the vias 62, the area of the layout structure is reduced.

Thus, according to this embodiment, reduction in the area of the capacitor cell can be achieved.

While the power lines 11 and 12 are formed in the interconnect layer provided on the back of the semiconductor chip in this embodiment, the configuration is not limited to this. According to the present disclosure, it is only required for the power lines to be formed on the back side of the transistors. The “back side of the transistors” as used herein refers to the side, with respect to the transistors, opposite to the side on which the local interconnects, the metal interconnects, etc. connected to the transistors are stacked one upon another.

Also, the power lines 11 and 12 may be formed in a plurality of interconnect layers.

While each four p-type and n-type transistors constitute capacitors in this embodiment, the number of transistors constituting capacitors is not limited to this.

In this embodiment, the metal interconnect 51 and the metal interconnect 54 in the M0 interconnect layer may be omitted. It is however preferable to place the metal interconnects 51 and 54 from the standpoint of increasing the interconnect capacitances.

### Other Configuration Example

The power lines on the back side of the transistors described above may also be formed using a semiconductor chip other than the semiconductor chip in which the transistors are formed.

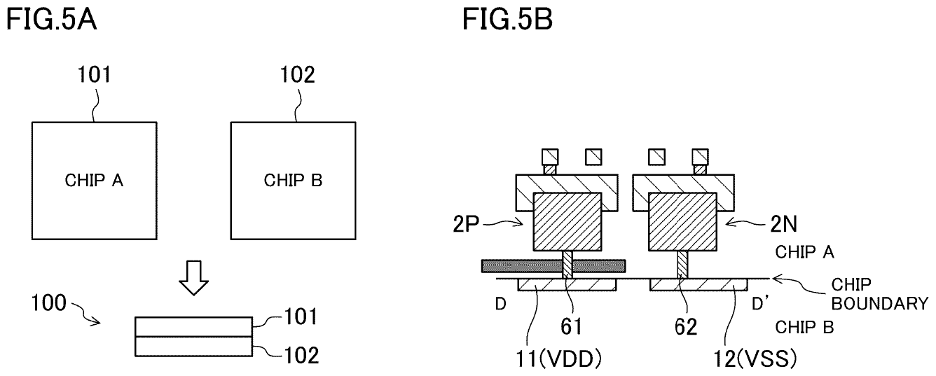

FIG. 5A shows another configuration example of the semiconductor integrated circuit device according to this embodiment. A semiconductor integrated circuit device 100 shown in FIG. 5A is constituted by a first semiconductor chip 101 (chip A) and a second semiconductor chip 102 (chip B) stacked one upon the other. In the chip A, standard cells including the above-described capacitor cell and the like are placed. In the chip B, power lines are formed in an interconnect layer provided on the surface. The chip B is bonded to the back of the chip A using bumps and the like.

FIG. 5B shows a cross section of this configuration example taken along line D-D′ in the capacitor cell of FIG. 1. As shown in FIG. 5B, the power line 11 supplying VDD and the power line 12 supplying VSS are formed in the interconnect layer provided on the surface of the chip B. The power line 11 is connected to the active region 2P in the chip A through the via 61, and the power line 12 is connected to the active region 2N in the chip A through the via 62.

With this configuration example, also, effects similar to those in the embodiment described above can be obtained. Note that, in this configuration example, also, the power lines 11 and 12 may be formed in a plurality of interconnect layers.

### Alteration 1 of First Embodiment

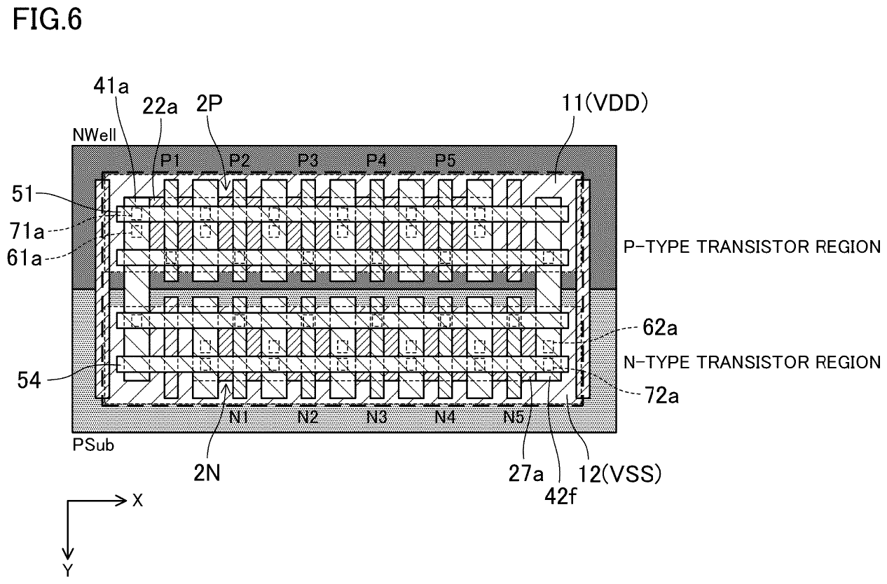

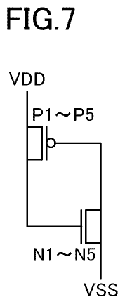

FIG. 6 is a plan view showing an example of the layout structure of a capacitor cell according to Alteration 1 of the first embodiment. FIG. 7 is a circuit diagram of the capacitor cell shown in FIG. 6.

The layout structure of FIG. 6 is basically similar to the layout structure of FIG. 1, except for the following points. A portion 22a of the transistor P1 on the left in the figure in the active region 2P is connected to the underlying power line 11 through a via 61a. Also, the local interconnect 41a in contact with the portion 22a is connected to the metal interconnect 51 through a via 71a. Similarly, a portion 27a of the transistor N5 on the right in the figure in the active region 2N is connected to the underlying power line 12 through a via 62a. Also, the local interconnect 42f in contact with the portion 27a is connected to the metal interconnect 54 through a via 72a.

In the layout structure of FIG. 6, the source and drain of the transistor P1 are connected to the power supply 11, and the source and drain of the transistor N5 are connected to the power line 12. Therefore, as shown in the circuit diagram of FIG. 7, the fixed value output unit is omitted, and the transistors P1 and N5 are also transistors constituting capacitors. VSS is directly supplied to the gates of the transistors P1 to P5 constituting the capacitors, and VDD is directly supplied to the gates of the transistors N1 to N5 constituting the capacitors.

According to this alteration, high-speed response to power supply noise in the capacitor cell can be enhanced.

### Alteration 2 of First Embodiment

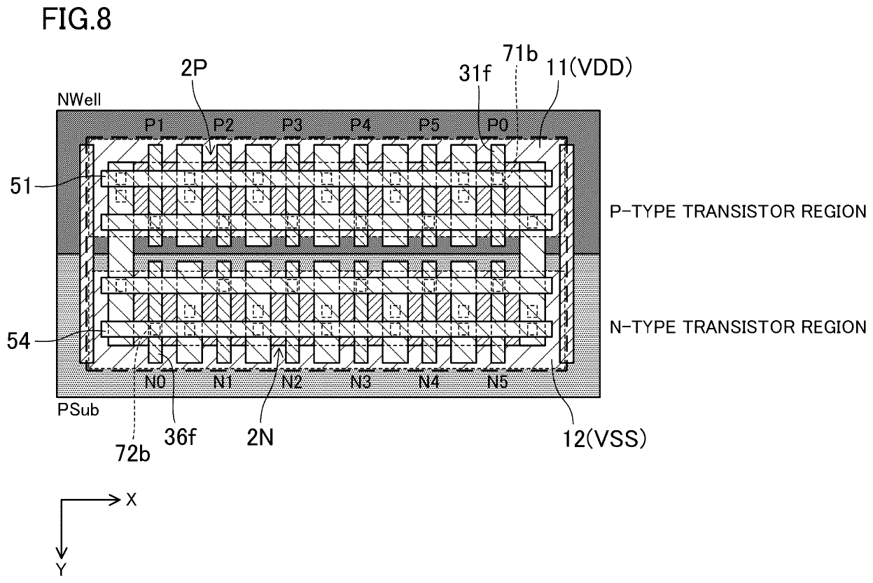

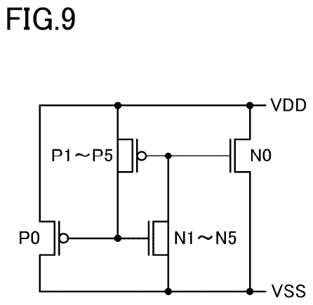

FIG. 8 is a plan view showing an example of the layout structure of a capacitor cell according to Alteration 2 of the first embodiment. FIG. 9 is a circuit diagram of the capacitor cell shown in FIG. 8.

The layout structure of FIG. 8 is basically similar to the layout structures of FIGS. 1 and 6, except for the following points. A transistor P0 is additionally provided on the right side of the transistor P5 in the figure. That is, the active region 2P further extends rightward from the right end of the transistor P5, and a gate interconnect 31f is placed in place of the dummy gate interconnect 38a, forming the transistor P0. The gate interconnect 31f is connected to the metal interconnect 51 through a via 71b. A transistor NO is additionally provided on the left side of the transistor N1 in the figure. That is, the active region 2N further extends leftward from the left end of the transistor N1, and a gate interconnect 36f is placed in place of the dummy gate interconnect 38b, forming the transistor NO. The gate interconnect 36f is connected to the metal interconnect 54 through a via 72b.

As shown in the circuit diagram of FIG. 9, in the layout structure of FIG. 8, VDD is applied to the gate of the transistor P0, and VSS is applied to the gate of the transistor NO. Therefore, the transistors P0 and NO are in the off state, being so-called off transistors in which no current flows.

According to this alteration, by forming the off transistors P0 and NO, the layout pattern of the active regions can be made more uniform. This can improve the yield of the semiconductor integrated circuit device, improve reliability, and prevent or reduce manufacturing variations.

### Second Embodiment

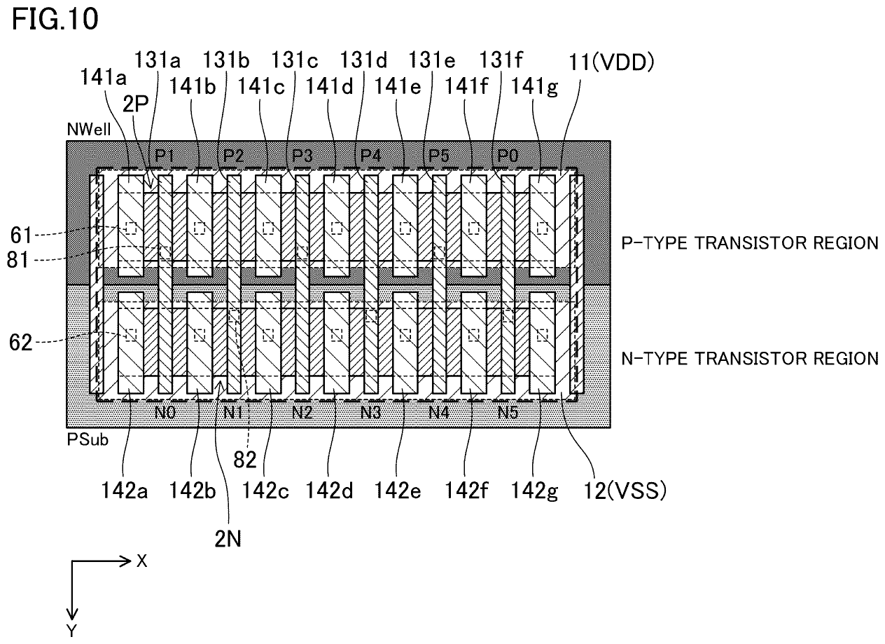

FIG. 10 is a plan view showing an example of the layout configuration of a capacitor cell according to the second embodiment. In this embodiment, description of configurations that can be easily known by analogy from the description in the first embodiment may be omitted or simplified.

In the layout structure of FIG. 10, as in the first embodiment, power lines 11 and 12 and active regions 2P and 2N are formed. The active region 2P is connected to the power line 11 through vias 61, and the active region 2N is connected to the power line 12 through vias 62. In a p-type transistor region on an n-type well, p-type transistors P1, P2, P3, P4, P5, and P0 are formed in this order from the left in FIG. 10. In an n-type transistor region on a p-type substrate, n-type transistors NO, N1, N2, N3, N4, and N5 are formed in this order from the left in FIG. 10.

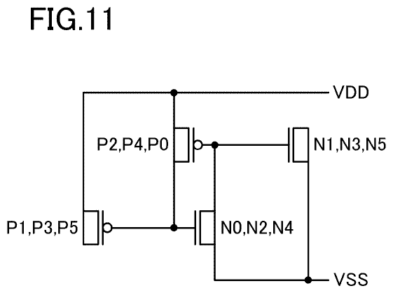

FIG. 11 is a circuit diagram of the capacitor cell shown in FIG. 10. As shown in FIG. 11, the transistors P2, P4, and P0 are connected to VDD at their sources and drains, and to VSS at their gates, thereby functioning as capacitors. The transistors NO, N2, and N4 are connected to VSS at their sources and drains, and to VDD at their gates, thereby functioning as capacitors. The transistors P1, P3, and P5 and the transistors N1, N3, and N5 are in the off state, being so-called off transistors.

In FIG. 10, formed are gate interconnects 131a, 131b, 131c, 131d, 131e, and 131f extending in parallel in the Y direction from the p-type transistor region over to the n-type transistor region. The gate interconnect 131a is to be the gates of the transistors P1 and NO, the gate interconnect 131b is to be the gates of the transistors P2 and N1, the gate interconnect 131c is to be the gates of the transistors P3 and N2, the gate interconnect 131d is to be the gates of the transistors P4 and N3, the gate interconnect 131e is to be the gates of the transistors P5 and N4, and the gate interconnect 131f is to be the gates of the transistors P0 and N5.

The gate interconnects 131a, 131c, and 131e are connected to the power line 11 through vias 81. VDD is therefore supplied to the transistors P1, P3, P5, NO, N2, and N4. The gate interconnects 131b, 131d, and 131f are connected to the power line 12 through vias 82. VSS is therefore supplied to the transistors P2, P4, P0, N1, N3, and N5.

Local interconnects 141a, 141b, 141c, 141d, 141e, 141f, 141g, 142a, 142b, 142c, 142d, 142e, 142f, and 142g extending in the Y direction are formed in a local interconnect layer. The local interconnects 141a, 141b, 141c, 141d, 141e, 141f, and 141g are connected to the portions that are to be the sources and drains of the transistors P1, P2, P3, P4, P5, and P0 in the active region 2P. The local interconnects 142a, 142b, 142c, 142d, 142e, 142f, and 142g are connected to the portions that are to be the sources and drains of the transistors NO, N1, N2, N3, N4, and N5 in the active region 2N.

According to this embodiment, the gate interconnects 131a, 131c, and 131e are connected to the power line 11 formed on the back side of the transistors, thereby being supplied with VDD. Also, the gate interconnects 131b, 131d, and 131f are connected to the power line 12 formed on the back side of the transistors, thereby being supplied with VSS. This makes it unnecessary to place metal interconnects, for supplying VDD and VSS to the gate interconnects, in the metal interconnect layer located above the local interconnect layer. Therefore, since a larger number of signal lines can be laid in the metal interconnect layer, the interconnect efficiency improves, permitting increase in the integration, and reduction in the area, of the semiconductor integrated circuit device.

While the transistors P2, P4, and P0 and the transistors NO, N2, and N4 function as capacitors in this embodiment, the combination of the transistors functioning as capacitors is not limited to this. For example, all of the gate interconnects 131a, 131b, 131c, 131d, 131e, and 131f may be connected to the power line 11 to make the transistors NO to N5 function as capacitors. Alternatively, all of the gate interconnects 131a, 131b, 131c, 131d, 131e, and 131f may be connected to the power line 12 to make the transistors P0 to P5 function as capacitors.

While the nanosheets have the structure of three sheets lying one above another and the cross-sectional shape of the sheet structure is illustrated as a rectangle in the above embodiments, the number of nanosheets, and the cross-sectional shape, of the sheet structure are not limited to these.

While nanosheet FETs are used as the transistors in the above embodiments, the type of the transistors is not limited to this. For example, fin FETs or other types of transistors may be used.

According to the present disclosure, a small-area capacitor cell can be implemented using power lines located right under transistors. The present disclosure is therefore useful for downsizing and higher integration of a semiconductor integrated circuit device, for example.

1. A semiconductor integrated circuit device including a standard cell that is a capacitor cell,
wherein
the standard cell includes
a first active region forming a channel, source, and drain of a first transistor of a first conductivity type and including a first nanosheet extending in a first direction as the channel of the first transistor,
a first power line formed on the back side of the first transistor, extending in the first direction, having an overlap with the first active region in planar view, and supplying a first power supply voltage,
vias formed at positions where the source and drain of the first transistor in the first active region overlap the first power line, to connect the source and drain to the first power line, and
a first gate interconnect extending in a second direction perpendicular to the first direction, being orthogonal to the first nanosheet in planar view, and being supplied with a second power supply voltage.

2. The semiconductor integrated circuit device of claim 1, wherein
the first power line is formed in an interconnect layer provided in a first semiconductor chip in which the first active region is formed.

3. The semiconductor integrated circuit device of claim 1, wherein
the first power line is formed in an interconnect layer provided in a second semiconductor chip bonded to the back of a first semiconductor chip in which the first active region is formed.

4. The semiconductor integrated circuit device of claim 1, wherein
the standard cell includes
a first metal interconnect extending in the first direction in a metal interconnect layer located above the first gate interconnect, being orthogonal to the first gate interconnect in planar view, and supplying the second power supply voltage, and
the first gate interconnect is connected to the first metal interconnect through a via.

5. The semiconductor integrated circuit device of claim 4, wherein
the standard cell includes
a second active region forming a channel, source, and drain of a second transistor of a second conductivity type and including a second nanosheet extending in the first direction as the channel of the second transistor,
a second power line formed on the back side of the second transistor, extending in the first direction, having an overlap with the second active region in planar view, and supplying the second power supply voltage,
a via formed at a position where the source of the second transistor in the second active region overlaps the second power line, to connect the source and the second power line, and
a first local interconnect extending in the second direction, and connected to the drain of the second transistor in the second active region, and
the first metal interconnect is electrically connected to the first local interconnect.

6. The semiconductor integrated circuit device of claim 5, wherein
the drain of the second transistor in the second active region is connected to the second power line through a via.

7. The semiconductor integrated circuit device of claim 1, wherein
the first active region forms a channel, source, and drain of a second transistor of the first conductivity type and includes a second nanosheet extending in the first direction as the channel of the second transistor, and
the first power supply voltage is supplied to the source and gate of the second transistor, and the second power supply voltage is supplied to the drain of the second transistor.

8. The semiconductor integrated circuit device of claim 1, wherein
the standard cell includes
a second active region forming a channel, source, and drain of a second transistor of a second conductivity type and including a second nanosheet extending in the first direction as the channel of the second transistor, and
a second power line formed on the back side of the second transistor, extending in the first direction, having an overlap with the second active region in planar view, and supplying the second power supply voltage, and
the first gate interconnect extends to overlap the second power line and is connected to the second power line through a via.
